(19) United States
(12) Patent Application Publication
(10) Pub. No.: US 2026/0018577 A1
(43) Pub. Date: Jan. 15, 2026

(54) SEMICONDUCTOR PACKAGE AND METHOD FOR MANUFACTURING THE SAME

(71) Applicant: Samsung Electronics Co., Ltd., Suwon-si (KR)

(72) Inventors: Kwang-Bae Kim, Suwon-si (KR); Jing Cheng Lin, Suwon-si (KR); Young Kun Jee, Suwon-si (KR); Yu Jen Chen, Suwon-si (KR)

(21) Appl. No.: 19/252,179

(22) Filed: Jun. 27, 2025

(30) Foreign Application Priority Data
Jul. 9, 2024 (KR) 10-2024-0090699

(51) Int. Cl. H01L 25/18; H01L 23/00; H01L 23/31; H10D 80/30; H10F 39/95

(52) U.S. Cl. CPC H01L 25/18; H10D 80/30; H10F 39/95; H01L 23/3135; H01L 24/16; H01L 24/32; H01L 24/73; H01L 2224/16145; H01L 2224/32145; H01L 2224/73204

(57) ABSTRACT

Provided is a semiconductor package including a substrate, a first chip on the substrate and including a photonic integrated circuit (PIC), a second chip on the first chip and including an electronic integrated circuit (EIC), a support block spaced apart from the second chip and bonded to an upper surface of the first chip, a molding layer on the first chip and at least partially surrounding the second chip and the support block, with an upper surface of the support block free of the molding layer, a micro-lens layer on the molding layer, the first chip, and the support block, and a first transparent adhesive layer between a lower surface of the micro-lens layer and an upper surface of the molding layer, and between the lower surface of the micro-lens layer and the upper surface of the support block.

### CROSS-REFERENCE TO RELATED APPLICATIONS

This U.S. non-provisional patent application claims priority under 35 U.S.C. § 119 to Korean Patent Application No. 10-2024-0090699, filed on Jul. 9, 2024, the entire contents of which are hereby incorporated by reference.

### BACKGROUND OF THE INVENTION

The present disclosure relates to a semiconductor package and a method for manufacturing the same, and more particularly, to a semiconductor package including an optical element and a method for manufacturing the same.

With the development of the electronics industry, demands for higher functionality, a higher speed, and a smaller size of an electronic component are increasing. In response to such trends, recent packaging technology is progressing in a direction in which a plurality of semiconductor chips are mounted within one package.

Demands for a portable device are rapidly increasing in the recent electronic product market, and as a result, miniaturization and weight reduction of electronic components mounted in such a product are continuously needed. Not only is technology for reducing an individual size of a mounted component helpful, but also semiconductor package technology for integrating multiple individual elements into one package is helpful in order to achieve miniaturization and weight reduction of the electronic components. In particular, a variety of structural characteristics, electrical characteristics, and optical characteristics according to characteristics and functions of the elements are useful for a semiconductor package in which a plurality of elements are integrated.

### SUMMARY OF THE INVENTION

The present disclosure provides a semiconductor package with improved structural stability and a method for manufacturing the same.

The present disclosure also provides a semiconductor package with improved optical characteristics and a method for manufacturing the same.

The present disclosure also provides a method for manufacturing a semiconductor package with a simplified manufacturing process and a semiconductor package manufactured therethrough.

Some embodiments of the inventive concepts provide a semiconductor package including a substrate, a first chip on the substrate and comprising a photonic integrated circuit (PIC), a second chip on the first chip and comprising an electronic integrated circuit (EIC), a support block spaced apart from the second chip and bonded to an upper surface of the first chip, a molding layer on the first chip and at least partially surrounding the second chip and the support block, wherein an upper surface of the support block is free of the molding layer, a micro-lens layer on the molding layer, the first chip, and the support block, and a first transparent adhesive layer between a lower surface of the micro-lens layer and an upper surface of the molding layer, and between the lower surface of the micro-lens layer and the upper surface of the support block.

In some embodiments of the inventive concepts, a method for manufacturing a semiconductor package includes providing a first chip comprising a photonic integrated circuit (PIC), the first chip further comprising a sensor portion and first chip pads on an active surface of the first chip, mounting a second chip on the first chip such that the second chip is electrically connected to the first chip pads, the second chip comprising an electronic integrated circuit (EIC), bonding a support block on the first chip such that the support block is located on the sensor portion of the first chip, forming a molding layer on the first chip, the second chip, and the support block, performing a thinning process on the molding layer to expose an upper surface of the support block, and adhering a micro-lens layer to an upper surface of the molding layer and the upper surface of the support block by using a transparent adhesive layer.

In some embodiments, an upper surface of the second chip may be exposed during the thinning process. The micro-lens layer may be adhered to the upper surface of the molding layer, the upper surface of the second chip, and the upper surface of the support block by using the transparent adhesive layer.

In some embodiments, the bonding of the support block on the first chip may include forming a first insulating layer on the active surface of the first chip, forming a second insulating layer on a lower surface of the support block, and bringing the first chip and the support block into contact such that the first insulating layer and the second insulating layer are in contact with each other on the sensor portion. The first insulating layer and the second insulating layer may include a same material.

In some embodiments, the support block may comprise silicon (Si). The second insulating layer may be formed by performing an oxidation process, a nitridation process, or an oxynitridation process on the lower surface of the support block.

In some embodiments of the inventive concepts, a method for manufacturing a semiconductor package includes providing a micro-lens layer, adhering a first chip and a support block on a surface of the micro-lens layer by using a transparent adhesive layer, the first chip comprising an electronic integrated circuit (EIC), forming a molding layer on the micro-lens layer, the first chip, and the support block, performing a thinning process on the molding layer to expose upper surfaces of connection terminals of the first chip and an upper surface of the support block, and bonding a second chip on the molding layer, the first chip, and the support block, the second chip comprising a photonic integrated circuit (PIC), wherein the second chip further comprises a sensor portion and chip pads on an active surface of the second chip, wherein the chip pads of the second chip are electrically connected to upper surfaces of the connection terminals of the first chip, and wherein the sensor portion is on the support block.

In some embodiments, the bonding of the second chip on the molding layer, the first chip, and the support block may include forming a first insulating layer by performing an oxidation process, a nitridation process, or an oxynitridation process on the upper surface of the support block, and bringing the second chip and the support block into contact such that the first insulating layer and a second insulating layer of the second chip are in contact with each other. The first insulating layer and the second insulating layer include a same material.

Some embodiments of the inventive concepts provide a semiconductor package including a first chip comprising a photonic integrated circuit (PIC) and a sensor portion on an upper surface of the first chip, a second chip on the upper surface of the first chip and comprising an electronic integrated circuit (EIC), a support block on the upper surface of the first chip, spaced apart from the second chip, and on the sensor portion, a molding layer on the first chip and at least partially surrounding the second chip and the support block, and a micro-lens layer on the molding layer and adhered to the support block, wherein a micro-lens of the micro-lens layer is above the support block, wherein the first chip comprises a first insulating layer at the upper surface of the first chip, wherein the support block comprises a second insulating layer at a lower surface of the support block, and wherein the first insulating layer and the second insulating layer are in contact with each other and include a same material.

### BRIEF DESCRIPTION OF THE FIGURES

The accompanying drawings are included to provide a further understanding of the inventive concepts, and are incorporated in and constitute a part of this specification. The drawings illustrate example embodiments of the inventive concepts and, together with the description, serve to explain principles of the inventive concepts. In the drawings:

FIG. 1 is a cross-sectional view for describing a semiconductor package according to embodiments of the inventive concepts;

FIG. 2 is an enlarged diagram of region A of FIG. 1;

FIGS. 3 to 10 are cross-sectional views for describing a semiconductor package according to embodiments of the inventive concepts;

FIGS. 11 to 19 are cross-sectional views for describing a method for manufacturing a semiconductor package according to embodiments of the inventive concepts; and

FIGS. 20 to 26 are cross-sectional views for describing a method for manufacturing a semiconductor package according to embodiments of the inventive concepts.

### DETAILED DESCRIPTION

A semiconductor package and a method for manufacturing the same according to the inventive concepts will be described hereinafter with reference to the accompanying drawings.

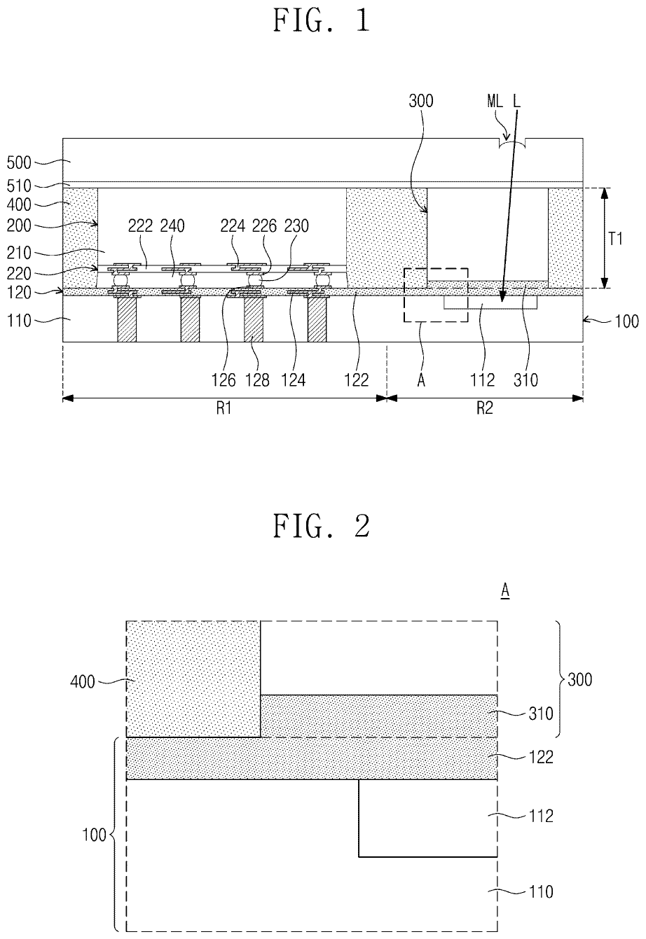

FIG. 1 is a cross-sectional view for describing the semiconductor package according to embodiments of the inventive concepts. FIG. 2 is an enlarged diagram of region A of FIG. 1.

Referring to FIGS. 1 and 2, a first chip 100 may be provided. The first chip 100 may be a wafer-level die made of semiconductor such as silicon (Si). An upper surface of the first chip 100 may be an active surface. That is, the first chip 100 may be provided in a face up form.

The first chip 100 may include a first semiconductor substrate 110, a first circuit layer 120, and chip vias 128.

The first semiconductor substrate 110 may be provided. The first semiconductor substrate 110 may include a semiconductor material. For example, the first semiconductor substrate 110 may be a single-crystalline silicon (Si) substrate. The first semiconductor substrate 110 may have an upper surface and a lower surface opposed to each other. The upper surface of the first semiconductor substrate 110 may be a front surface of the first semiconductor substrate 110, and the lower surface of the first semiconductor substrate 110 may be a rear surface of the first semiconductor substrate 110. Here, the front surface of the first semiconductor substrate 110 may be defined as one surface on which integrated elements of the first semiconductor substrate 110 are formed or mounted, or a line, a pad, or the like is formed, and the rear surface of the first semiconductor substrate 110 may be defined as an opposite surface opposed to the front surface.

The first chip 100 may have a first integrated element provided onto the upper surface of the first semiconductor substrate 110. The first integrated element may include a photonic integrated circuit (PIC).

The first semiconductor substrate 110 may have a first region R1 and a second region R2 disposed horizontally spaced apart from each other. For example, the first region R1 and the second region R2 may be horizontally adjacent to each other. The first region R1 may be a region on which a second chip 200 to be described later is mounted. The second region R2 may be a region in which a support block 300 to be described later is disposed. In other words, the first region R1 may be a region in which the first chip 100 receives an electrical signal from the second chip 200, and the second region R2 may be a region in which the first chip 100 receives an optical signal from the outside (e.g., from an external source).

The first semiconductor substrate 110 may further include a sensor portion 112. The sensor portion 112 may be disposed on the second region R2. The sensor portion 112 may be exposed onto the upper surface of the first semiconductor substrate 110. The sensor portion 112 may receive light to change to an electrical signal. In other words, the sensor portion 112 may receive light and convert the light to an electrical signal.

The first chip 100 may have a first circuit layer 120 provided onto the upper surface of the first semiconductor substrate 110. The first circuit layer 120 may include a first insulating layer 122 and a first element line portion 124.

The upper surface of the first semiconductor substrate 110 may be covered by the first insulating layer 122. For example, the first chip 100 may include the first insulating layer 122 at an upper surface of the first chip 100. The first insulating layer 122 may be on (e.g., may cover) a first integrated element and the sensor portion 112 formed in the first semiconductor substrate 110. That is, the sensor portion 112 and the first integrated element may not be exposed by the first insulating layer 122. The first insulating layer 122 may include an oxide, a nitride, or an oxynitride of a material that constitutes (i.e., that is included in) the first semiconductor substrate 110. For example, the first insulating layer 122 may include at least one of silicon oxide (SiO), silicon nitride (SiN), or silicon oxynitride (SiON).

The first element line portion 124 connected to the first integrated element may be provided in the first insulating layer 122. The first element line portion 124 may be disposed on the first region R1. The first element line portion 124 may include line patterns buried in the first insulating layer 122. For example, the line patterns may include reline patterns for horizontal lining and via patterns for vertical connection. The first element line portion 124 may vertically penetrate (i.e., may vertically extend in) the first insulating layer 122 to be connected to the first integrated element. The first element line portion 124 may be located between an upper surface and a lower surface of the first insulating layer 122. For example, the first element line portion 124 may include copper (Cu) or tungsten (W).

First chip pads 126 may be provided on the upper surface of the first insulating layer 122. The first chip pads 126 may be disposed on the first region R1. The first chip pads 126 may be exposed onto the upper surface of the first insulating layer 122. The first chip pads 126 may protrude onto the upper surface of the first insulating layer 122. As another example, the upper surfaces of the first chip pads 126 may be coplanar with the upper surface of the first insulating layer 122. The first chip pads 126 may be connected to the first element line portion 124. For example, the first chip pads 126 may include copper (Cu) or tungsten (W).

The first chip 100 may further include chip vias 128 vertically penetrating the first semiconductor substrate 110 to be connected to the first element line portion 124 or the first integrated element. The chip vias 128 may be disposed on the first region R1. The chip vias 128 may be patterns for vertical lining. The chip vias 128 may vertically penetrate the first semiconductor substrate 110 to be partially connected to a lower surface of the first element line portion 124. The chip vias 128 may vertically penetrate the first semiconductor substrate 110 to be exposed onto the lower surface of the first semiconductor substrate 110. For example, the chip vias 128 may include tungsten (W).

The second chip 200 may be provided on the first chip 100. The second chip 200 may be disposed on the first region R1. The second chip 200 may be a wafer-level die made of semiconductor such as silicon (Si). A lower surface of the second chip 200 may be an active surface. That is, the second chip 200 may be provided in a face down form. A distance from an upper surface of the first chip 100 to an upper surface of the second chip 200 may be in a range of about 1 micrometer (μm) to about 500 μm.

The second chip 200 may include a second semiconductor substrate 210 and a second circuit layer 220.

The second semiconductor substrate 210 may be provided. The second semiconductor substrate 210 may include a semiconductor material. For example, the second semiconductor substrate 210 may be a single-crystalline silicon (Si) substrate. The second semiconductor substrate 210 may have an upper surface and a lower surface opposed to each other. The lower surface of the second semiconductor substrate 210 may be a front surface of the second semiconductor substrate 210, and the upper surface of the second semiconductor substrate 210 may be a rear surface of the second semiconductor substrate 210.

The second chip 200 may have a second integrated element provided onto the lower surface of the second semiconductor substrate 210. The second integrated element may include an electronic integrated circuit (EIC).

The second chip 200 may have a second circuit layer 220 provided onto the lower surface of the second semiconductor substrate 210. The second circuit layer 220 may include a second insulating layer 222 and a second element line portion 224.

The lower surface of the second semiconductor substrate 210 may be covered by the second insulating layer 222. The second insulating layer 222 may be on (e.g., may cover) the second integrated element formed in the second semiconductor substrate 210. That is, the second integrated element may not be exposed by the second insulating layer 222. For example, the second insulating layer 222 may include at least one of silicon oxide (SiO), silicon nitride (SiN), or silicon oxynitride (SiON).

The second element line portion 224 connected to the second integrated element may be provided in the second insulating layer 222. The second element line portion 224 may include line patterns buried in the second insulating layer 222. For example, the line patterns may include reline patterns for horizontal lining and via patterns for vertical connection. The second element line portion 224 may vertically penetrate the second insulating layer 222 to be connected to the second integrated element. The second element line portion 224 may be located between an upper surface and a lower surface of the second insulating layer 222. For example, the second element line portion 224 may include copper (Cu) or tungsten (W).

Second chip pads 226 may be provided on the lower surface of the second insulating layer 222. The second chip pads 226 may be exposed onto the lower surface of the second insulating layer 222. The second chip pads 226 may protrude onto the lower surface of the second insulating layer 222. As another example, the lower surfaces of the second chip pads 226 may be coplanar with the lower surface of the second insulating layer 222. The second chip pads 226 may be connected to the second element line portion 224. For example, the second chip pads 226 may include copper (Cu) or tungsten (W).

The second chip 200 may be mounted on the first chip 100. The second chip 200 may be mounted on the first chip 100 in a flip chip manner. For example, the second chip 200 may be disposed on the first circuit layer 120 of the first chip 100 on the first region R1. The second circuit layer 220 of the second chip 200 may face an upper surface of the first chip 100. The second chip pads 226 of the second chip 200 may be vertically aligned with the first chip pads 126 of the first chip 100. First connection terminals 230 may be provided between the first chip pads 126 and the second chip pads 226. The first connection terminals 230 may be connected to upper surfaces of the first chip pads 126 and lower surfaces of the second chip pads 226. The second chip 200 may be electrically connected to the first chip 100 through the first connection terminals 230.

A first under fill layer 240 may be provided between the first chip 100 and the second chip 200. The first under fill layer 240 may be in (e.g., may fill) a space between the first chip 100 and the second chip 200, and may surround the first connection terminals 230.

The support block 300 may be provided on the first chip 100. The support block 300 may be disposed on the second region R2. The support block 300 may be disposed horizontally spaced apart from the second chip 200. The support block 300 may be located above the sensor portion 112. For example, the support block 300 may be on the sensor portion 112. The support block 300 may entirely cover the sensor portion 112. The support block 300 may have a thickness Tl in a range of about 1 μm to about 500 μm. An upper surface of the support block 300 may be located at the same level as (i.e., may be coplanar with) the upper surface of the second chip 200. The support block 300 may transmit light (i.e., may pass light) to be received by the first chip 100. The support block 300 may include silicon (Si), more specifically, bulk silicon (Si), but the inventive concepts are not limited thereto. The support block 300 may be composed of various materials depending on light to be received by the first chip 100. For example, the support block 300 may transmit light (i.e., may pass light) having a wavelength in a range of about 700 nanometers (nm) to about 1500 nm.

The support block 300 may have a third insulating layer 310 provided onto a lower surface of the support block 300. For example, the support block 300 may include the third insulating layer 310 at the lower surface of the support block 300.

The third insulating layer 310 may cover the lower surface of the support block 300. The third insulating layer 310 may have a thickness in a range of about 1 nm to about 100 nm. The third insulating layer 310 may include an oxide, a nitride, or an oxynitride of a material that constitutes (i.e., that is included in) the support block 300. For example, the third insulating layer 310 may include at least one of silicon oxide (SiO), silicon nitride (SiN), or silicon oxynitride (SiON). For example, the third insulating layer 310 may be a layer formed by performing an oxidation process, a nitridation process, or an oxynitridation process on the lower surface of the support block 300. As another example, the third insulating layer 310 may be a layer formed by natural oxidation, nitridation, or oxynitridation of the lower surface or a lower portion of the support block 300. The third insulating layer 310 may include the same material as the first insulating layer 122. As another example, the third insulating layer 310 and the first insulating layer 122 may include an oxide, nitride, or oxynitride of the same material, and may include different materials.

According to some embodiments, the third insulating layer 310 may be composed of silicon oxide (SiO), silicon nitride (SiN), or silicon oxynitride (SiON), and the remaining part of the support block 300 may be composed of silicon (Si). FIG. 2 illustrates that the third insulating layer 310 contains oxygen or nitrogen, but a concentration of oxygen or nitrogen in the third insulating layer 310 is not limited. For example, the concentration of oxygen or nitrogen in the third insulating layer 310 may be uniform.

According to other embodiments, the concentration of oxygen or nitrogen in the third insulating layer 310 may become smaller from the lower surface of the support block 300 to the inside of the support block 300.

Still referring to FIGS. 1 and 2, the support block 300 may be disposed on the first chip 100 on the second region R2. The lower surface of the support block 300 may be in contact with the upper surface of the first chip 100. More specifically, a lower surface of the third insulating layer 310 of the support block 300 may be in contact with the upper surface of the first insulating layer 122 of the first chip 100.

The first insulating layer 122 of the first chip 100 and the third insulating layer 310 of the support block 300 may be bonded to each other on an interface between the support block 300 and first chip 100. In other words, the support block 300 may be bonded to an upper surface of the first chip 100. In this case, the first insulating layer 122 and the third insulating layer 310 may form a hybrid bonding of an oxide, a nitride, or an oxynitride. In the present disclosure, the term “a hybrid bonding” means a bonding in which two components including the same type of material fuse at an interface thereof. For example, the first insulating layer 122 and the third insulating layer 310 bonded to each other may have a continuous configuration, and a boundary surface between the first insulating layer 122 and the third insulating layer 310 may not be visually viewed. For example, the first insulating layer 122 and the third insulating layer 310 may be composed of the same material (for example, silicon oxide (SiO), or the like), and thus there may not be an interface between the first insulating layer 122 and the third insulating layer 310. That is, the first insulating layer 122 and the third insulating layer 310 may be provided as one component. In other words, the first insulating layer 122 and the third insulating layer 310 may together form a monolithic structure. For example, the first insulating layer 122 may be bonded to and may be integrally formed with the third insulating layer 310.

According to embodiments of the inventive concepts, the third insulating layer 310 formed by partially oxidizing or nitriding a translucent layer provided on a lower portion of the support block 300, and may be bonded to and may be integrally formed with the first insulating layer 122. Accordingly, the support block 300 may be robustly attached or bonded to the first chip 100, and the semiconductor package with improved structural stability may be provided. In addition, a number of material layers transmitted by light may be small in a path L of the light transmitting the translucent layer and entering the sensor portion 112 of the first chip 100. Moreover, the inside of the support block 300, that is, the translucent layer may be composed of one material layer, and thus may be provided with a material having high transmittance for the light to be received by the first chip 100 so that light loss may be small. That is, the semiconductor package with improved optical characteristics may be provided.

Still referring to FIGS. 1 and 2, a first molding layer 400 may be provided on the first chip 100. The first molding layer 400 may surround the second chip 200 and the support block 300 on the first chip 100. It will be understood that “an element A surrounds an element B” (or similar language) as used herein means that the element A is at least partially around the element B but does not necessarily mean that the element A completely encloses the element B. The second chip 200 and the support block 300 may be exposed onto an upper surface of the first molding layer 400. In other words, an upper surface of the second chip 200 and an upper surface of the support block 300 may be free of the first molding layer 400. The upper surface of the second chip 200 and the upper surface of the support block 300 may be coplanar with the upper surface of the first molding layer 400. The first molding layer 400 may include an insulating material. For example, the first molding layer 400 may include an insulating polymer material such as an epoxy molding compound (EMC).

A micro-lens layer 500 may be provided on the first molding layer 400. For example, the micro-lens layer 500 may be on the first chip 100, the second chip 200, the support block 300, and the first molding layer 400. The micro-lens layer 500 may be on (e.g., may cover) all of the first region R1 and the second region R2. More specifically, the micro-lens layer 500 may be on (e.g., may cover) the upper surface of the second chip 200, the upper surface of the first molding layer 400 and the upper surface of the support block 300. The micro-lens layer 500 may have a micro-lens ML formed on an upper surface of the micro-lens layer 500. For example, as illustrated in FIG. 1, the micro-lens ML may be provided on the upper surface of the micro-lens layer 500 in a recessed form. The micro-lens ML may have a shape of a spherical surface in which a bottom surface thereof is convex upward. As another example, the micro-lens ML may have a shape of a spherical surface protruding from the upper surface of the micro-lens layer 500 upward. As a further example, the micro-lens ML may be provided to the micro-lens layer 500 in various forms as needed. The micro-lens ML may be located above the sensor portion 112 in the second region R2. The micro-lens layer 500 may transmit light to be received by the first chip 100. For example, the sensor portion 112 may receive light that enters the micro-lens layer 500 and passes (i.e., transmits) through the support block 300. The micro-lens layer 500 may include silicon (Si), glass, or various transparent materials, but the inventive concepts are not limited thereto. The micro-lens layer 500 may be composed of various materials depending on light to be received by the first chip 100. For example, the micro-lens layer 500 may transmit light having a wavelength in a range of about 700 nm to about 1500 nm.

The micro-lens layer 500 may be adhered onto the first molding layer 400. The micro-lens layer 500 may be adhered to the upper surface of the first molding layer 400, the upper surface of the second chip 200 and the upper surface of the support block 300 by using a first adhesive layer 510. The first adhesive layer 510 may be interposed between the second chip 200, the first molding layer 400, and the support block 300 and the micro-lens layer 500. For example, the first adhesive layer 510 may be between a lower surface of the micro-lens layer 500 and the upper surface of the second chip 200, may be between the lower surface of the micro-lens layer 500 and the upper surface of the support block 300, and may be between the lower surface of the micro-lens layer 500 and the upper surface of the first molding layer 400. The first adhesive layer 510 may include a transparent material so as to transmit light entering through the micro-lens ML of the micro-lens layer 500 to the sensor portion 112 of the first chip 100. The first adhesive layer 510 may transmit light having a wavelength in a range of about 700 nm to about 1500 nm. The first adhesive layer 510 may have a refractive index in a range of about 3.15 to about 3.85. The first adhesive layer 510 may include an optical glue. As used herein, the first adhesive layer 510 may also be referred to as a first transparent adhesive layer.

According to embodiments of the inventive concepts, since the micro-lens layer 500 is adhered using the first adhesive layer 510, a process of manufacturing a semiconductor package may be simplified. In addition, there may be fewer defects such as a void in the first adhesive layer 510. Accordingly, there may be less loss of light that transmits through the first adhesive layer 510. That is, the semiconductor package with improved optical characteristics may be provided. This will be described with a method for manufacturing a semiconductor package in more detail later.

Hereinafter, for convenience of description, duplicate descriptions of those described with reference to FIGS. 1 and 2 above will be brief or omitted, and differences will be described in detail. The same reference numerals or symbols will be provided with respect to the same configurations as the semiconductor package according to embodiments of the inventive concepts described above.

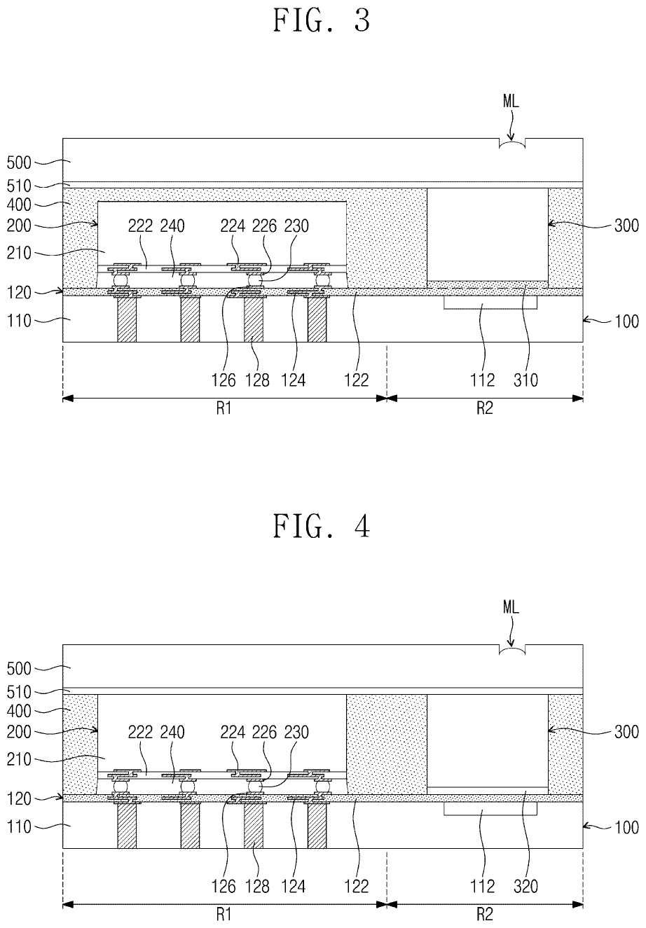

FIG. 3 is a cross-sectional view for describing a semiconductor package according to embodiments of the inventive concepts.

Referring to FIG. 3, the first molding layer 400 may be provided on the first chip 100. The first molding layer 400 may surround the second chip 200 and the support block 300 on the first chip 100. The first molding layer 400 may be on (e.g., may cover) the second chip 200. For example, the first molding layer 400 may be on an upper surface of the second chip 200, and a portion of the first molding layer 400 may be between the upper surface of the second chip 200 and the first adhesive layer 510. The support block 300 may be exposed onto the upper surface of the first molding layer 400. In other words, an upper surface of the support block 300 may be free of the first molding layer 400. The upper surface of the support block 300 may be coplanar with the upper surface of the first molding layer 400. The upper surface of the second chip 200 may not be exposed onto the upper surface of the first molding layer 400. In other words, the first molding layer 400 may be on the upper surface of the second chip 200.

The micro-lens layer 500 may be provided on the first molding layer 400. The micro-lens layer 500 may be on (e.g., may cover) all of the first region R1 and the second region R2. More specifically, the micro-lens layer 500 may be on (e.g., may cover) the upper surface of the first molding layer 400 and the upper surface of the support block 300.

The micro-lens layer 500 may be adhered onto the first molding layer 400. The micro-lens layer 500 may be adhered to the upper surface of the first molding layer 400, and the upper surface of the support block 300 by using the first adhesive layer 510. The first adhesive layer 510 may be spaced apart from the upper surface of the second chip 200 with the first molding layer 400 therebetween.

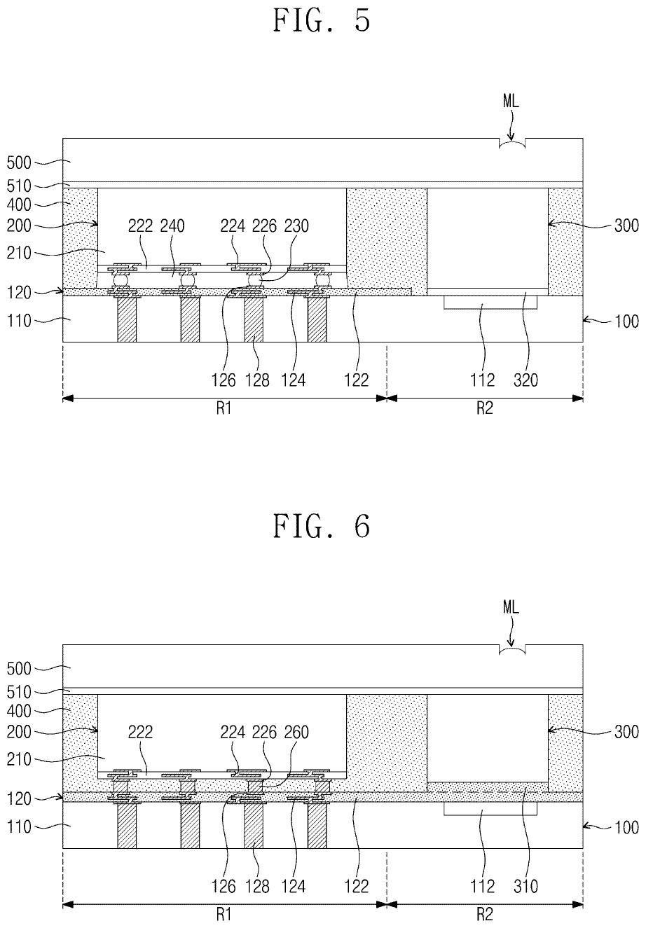

FIGS. 4 and 5 are cross-sectional views for describing a semiconductor package according to embodiments of the inventive concepts.

Referring to FIG. 4, the support block 300 may not have a third insulating layer 310. Described differently, the support block 300 may be a material layer composed of one material. For example, the support block 300 may include bulk silicon (Si).

The support block 300 may be adhered onto the first chip 100. The support block 300 may be adhered to an upper surface of the first insulating layer 122 on the second region R2 by using a second adhesive layer 320. The second adhesive layer 320 may be interposed between the support block 300 and the first insulating layer 122. In other words, the second adhesive layer 320 may be between a lower surface of the support block 300 and an upper surface of the first chip 100. For example, the support block 300 may be bonded to the upper surface of the first chip 100 by the second adhesive layer 320. The second adhesive layer 320 may include a transparent material so as to transmit light entering through the micro-lens ML of the micro-lens layer 500 to the sensor portion 112 of the first chip 100. The second adhesive layer 320 may transmit light having a wavelength in a range of about 700 nm to about 1500 nm. The second adhesive layer 320 may have a refractive index in a range of about 3.15 to about 3.85. The second adhesive layer 320 may include an optical glue. As used herein, the second adhesive layer 320 may also be referred to as a second transparent adhesive layer.

According to other embodiments, as illustrated in FIG. 5, the first insulating layer 122 may not be provided onto the second region R2. Described differently, the first insulating layer 122 may be on (e.g., may cover) the first semiconductor substrate 110 on the first region R1, and may expose an upper surface of the first semiconductor substrate 110 on the second region R2. The first insulating layer 122 may not be on (e.g., may not cover) the sensor portion 112.

The support block 300 may be adhered (i.e., bonded) onto the first chip 100 on the second region R2. The support block 300 may be adhered onto the upper surface of the first semiconductor substrate 110 exposed on the second region R2. The support block 300 may be adhered onto the sensor portion 112. The support block 300 may be adhered to the upper surface of the first semiconductor substrate 110 on the second region R2 by using the second adhesive layer 320. The second adhesive layer 320 may be interposed between the support block 300 and the first semiconductor substrate 110.

FIG. 6 is a cross-sectional view for describing a semiconductor package according to embodiments of the inventive concepts.

Referring to FIG. 6, instead of the first connection terminals 230, the second chip 200 may further include chip bumps 260 connected to the second chip pads 226. The chip bumps 260 may be connected to lower surfaces of the second chip pads 226. The chip bumps 260 may be connected to upper surfaces of the first chip pads 126. The chip bumps 260 may include a solder bump. According to other embodiments, instead of the chip bumps 260, conductive posts connecting the first chip pads 126 and the second chip pads 226 may be provided.

The first under fill layer 240 (see FIG. 1) may not be provided between the first chip 100 and the second chip 200. The first molding layer 400 may surround the second chip 200 on the first chip 100, and may extend between the first chip 100 and the second chip 200. The first molding layer 400 may be in (e.g., may fill) a space between the first chip 100 and the second chip 200, and may surround the chip bumps 260.

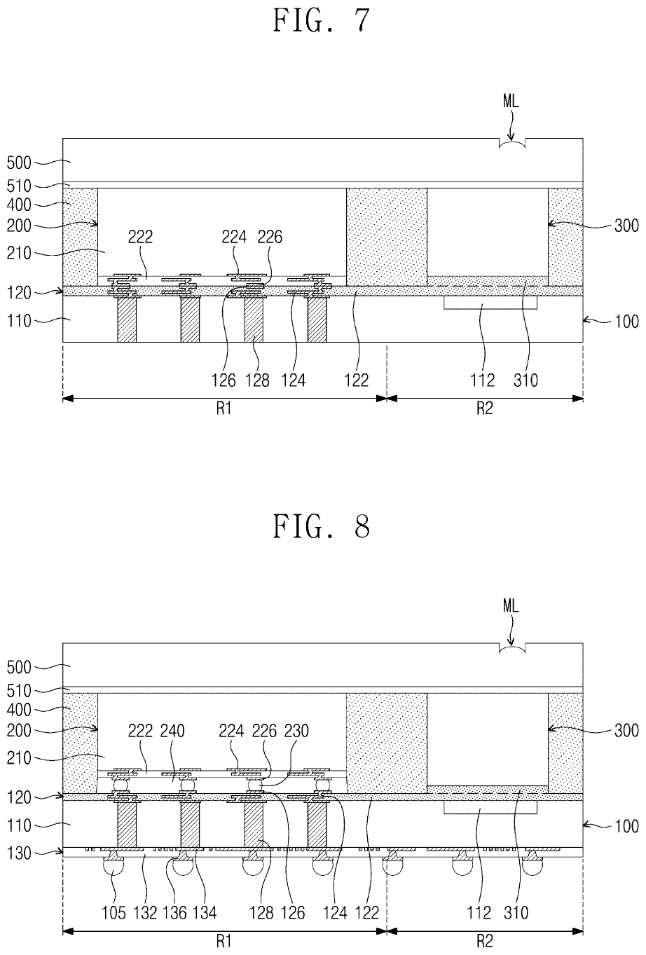

FIG. 7 is a cross-sectional view for describing a semiconductor package according to embodiments of the inventive concepts.

Referring to FIG. 7, the second chip 200 may be bonded to the first chip 100.

The first chip 100 may have the first chip pads 126. The upper surfaces of the first chip pads 126 may be coplanar with the upper surface of the first insulating layer 122.

The second chip 200 may have the second chip pads 226. The lower surfaces of the second chip pads 226 may be coplanar with the lower surface of the second insulating layer 222.

The second chip 200 may be mounted on the first chip 100. The lower surface of the second chip 200 may be in contact with the upper surface of the first chip 100. The first chip pads 126 and the second chip pads 226 may be bonded to each other on an interface between the first chip 100 and the second chip 200. In this case, the first chip pads 126 and the second chip pads 226 may form an intermetallic hybrid bonding. For example, the first chip pads 126 and the second chip pads 226 bonded to each other may have continuous configurations, and boundary surfaces between the first chip pads 126 and the second chip pads 226 may not be visually viewed. For example, the first chip pads 126 and the second chip pads 226 may be composed of the same material (for example, copper (Cu), or the like), and thus there may not be interfaces between the first chip pads 126 and the second chip pads 226. That is, the first chip pads 126 and the second chip pads 226 may be provided as one component. For example, the first chip pads 126 may be bonded to and may be integrally formed with (e.g., may be in contact with) the second chip pads 226. The first insulating layer 122 and the second insulating layer 222 may be in contact with each other on an interface between the first chip 100 and the second chip 200.

FIG. 8 is a cross-sectional view for describing a semiconductor package according to embodiments of the inventive concepts.

Referring to FIG. 8, the first chip 100 may further include a lining layer 130 provided to an inactive surface of the first chip 100. The lining layer 130 may include a fourth insulating layer 132 and a third element line portion 134.

The lower surface of the first semiconductor substrate 110 may be covered by the fourth insulating layer 132. The fourth insulating layer 132 may be on (e.g., may cover) the lower surface of the first semiconductor substrate 110. The fourth insulating layer 132 may include an oxide, a nitride, or an oxynitride of a material that constitutes the first semiconductor substrate 110. For example, the fourth insulating layer 132 may include at least one of silicon oxide (SiO), silicon nitride (SiN), or silicon oxynitride (SiON).

The third element line portion 134 connected to the chip vias 128 may be provided in the fourth insulating layer 132. The third element line portion 134 may include line patterns buried in the fourth insulating layer 132. For example, the line patterns may include reline patterns for horizontal lining and via patterns for vertical connection. The third element line portion 134 may vertically penetrate the fourth insulating layer 132 to be connected to the chip vias 128. The third element line portion 134 may be located between an upper surface and a lower surface of the fourth insulating layer 132. For example, the third element line portion 134 may include copper (Cu) or tungsten (W).

Third chip pads 136 may be provided on the lower surface of the fourth insulating layer 132. The third chip pads 136 may be exposed onto the lower surface of the fourth insulating layer 132. The third chip pads 136 may protrude onto the lower surface of the fourth insulating layer 132. As another example, the lower surfaces of the third chip pads 136 may be coplanar with the lower surface of the fourth insulating layer 132. The third chip pads 136 may be connected to the third element line portion 134. For example, the third chip pads 136 may include copper (Cu) or tungsten (W).

Connection terminals 105 may be provided on the lower surface of the lining layer 130. The connection terminals 105 may be connected to the third chip pads 136. The connection terminals 105 may include a solder ball or a solder bump, and the semiconductor package may be provided in a form of a ball grid array (BGA), a fine ball grid array (FBGA), or a land grid array (LGA) depending on a type and an arrangement of the connection terminals 105.

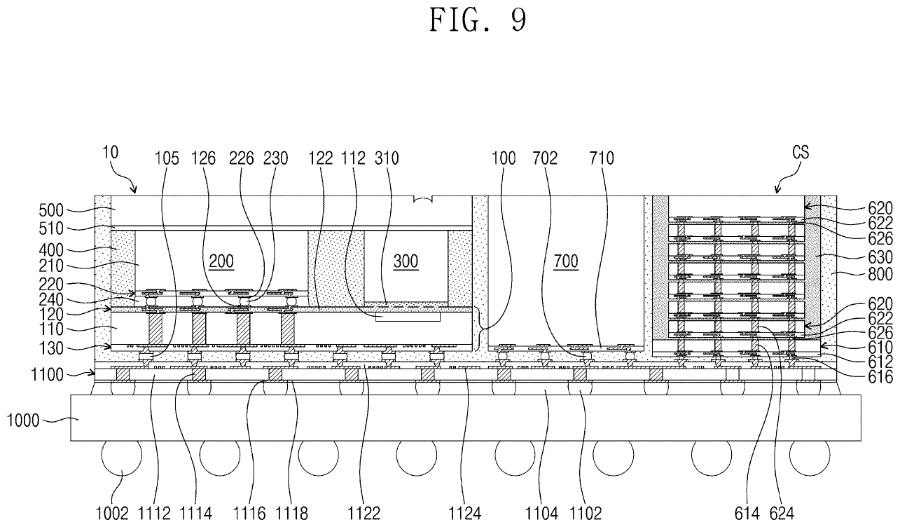

FIG. 9 is a cross-sectional view for describing a semiconductor package according to embodiments of the inventive concepts.

Referring to FIG. 9, a package substrate 1000 may be provided. The package substrate 1000 may include a printed circuit board (PCB) having a signal pattern on an upper surface thereof. As another example, the package substrate 1000 may have a structure in which an insulating layer and a lining layer are alternately stacked. The package substrate 1000 may have pads disposed on the upper surface thereof.

External terminals 1002 may be disposed under the package substrate 1000. Specifically, the external terminals 1002 may be disposed on terminal pads disposed on a lower surface of the package substrate 1000. The external terminals 1002 may include a solder ball or a solder bump, and the semiconductor package may be provided in a form of a ball grid array (BGA), a fine ball grid array (FBGA), or a land grid array (LGA) depending on a type and an arrangement of the external terminals 1002.

An interposer substrate 1100 may be provided on the package substrate 1000. The interposer substrate 1100 may be a silicon (Si) interposer substrate. For example, the interposer substrate 1100 may include a silicon layer 1112, interposer vias 1114 vertically penetrating the silicon layer 1112, interposer lower pads 1116 provided on a lower surface of the silicon layer 1112 to be connected to the interposer vias 1114, an interposer protective film 1118 provided on the lower surface of the silicon layer 1112 to surround the interposer lower pads 1116, and an interposer line portion provided on an upper surface of the silicon layer 1112.

The silicon layer 1112 may be a silicon (Si) substrate. The interposer vias 1114 may completely vertically penetrate the silicon layer 1112. That is, upper surfaces of the interposer vias 1114 may be exposed onto the upper surface of the silicon layer 1112, and lower surfaces of the interposer vias 1114 may be exposed onto the lower surface of the silicon layer 1112. The interposer vias 1114 may include metal such as copper (Cu).

The interposer lower pads 1116 may be disposed on lower surfaces of the interposer vias 1114 on a lower surface of the silicon layer 1112. The interposer lower pads 1116 may include metal such as copper (Cu).

The interposer protective film 1118 may be disposed on the lower surface of the silicon layer 1112. The interposer protective film 1118 may expose the lower surfaces of the interposer lower pads 1116. The interposer protective film 1118 may include a photoimageable dielectric (PID). For example, the photoimageable dielectric may include at least one of photoimageable polyimide, polybenzoxazole (PBO), a phenol-based polymer or a benzocyclobutene-based polymer.

The interposer line portion may include at least one substrate line layer. The substrate line layers may each include a first substrate insulating pattern 1122 and a first substrate line pattern 1124 in the first substrate insulating pattern 1122. The first substrate line pattern 1124 may be electrically connected to the interposer vias 1114. The first substrate insulating pattern 1122 may include an insulating polymer or the photoimageable dielectric (PID). The first substrate line pattern 1124 may be provided in the first substrate insulating pattern 1122. The first substrate line pattern 1124 may have a damascene structure. For example, the first substrate line pattern 1124 may have a head portion and a tail portion integrally connected to each other. The head portion may be a line portion or pad portion horizontally expanding lines in the substrate line layers. The tail portion may be a via portion vertically connecting the lines in the substrate line layers. The first substrate line pattern 1124 may have a conductive material. For example, the first substrate line pattern 1124 may include copper (Cu).

The head portion of the first substrate line pattern 1124 of the uppermost substrate line layer among the substrate line layers may correspond to interposer upper pads of the interposer substrate 1100. The interposer upper pads may be substrate pads for mounting a first chip structure 10, a chip stack CS, and a fourth semiconductor chip 700.

Unlike what is illustrated in FIG. 9, the interposer substrate 1100 may be a redistribution substrate. For example, the interposer substrate 1100 may include at least two substrate line layers. The substrate line layers may each include a substrate insulating pattern and a substrate line pattern in the substrate insulating pattern. The substrate line pattern of any one substrate line layer and the substrate line pattern of another adjacent substrate line layer may be electrically connected to each other. Hereinafter, description will be made while still referring to FIG. 9.

The interposer substrate 1100 may be mounted on an upper surface of the package substrate 1000. Substrate terminals 1102 may be disposed on a lower surface of the interposer substrate 1100. The substrate terminals 1102 may be provided between the pads of the package substrate 1000 and the interposer lower pads 1116 of the interposer substrate 1100. The substrate terminals 1102 may electrically connect the interposer substrate 1100 to the package substrate 1000. For example, the interposer substrate 1100 may be mounted on the package substrate 1000 in a flip chip manner. The substrate terminals 1102 may include a solder ball, solder bump, or the like.

A first under fill film 1104 may be provided between the package substrate 1000 and the interposer substrate 1100. The first under fill film 1104 may be in (e.g., may fill) a space between the package substrate 1000 and the interposer substrate 1100, and may surround the substrate terminals 1102.

The first chip structure 10 may be disposed on the interposer substrate 1100. The first chip structure 10 may be the semiconductor package described with reference to FIGS. 1 to 8.

The first chip structure 10 may be mounted on the interposer substrate 1100. For example, the first chip structure 10 may be connected to the first substrate line pattern 1124 of the interposer substrate 1100 through the connection terminals 105 of the first chip 100. The connection terminals 105 may be provided between the first substrate line pattern 1124 of the interposer substrate 1100 and the lining layer 130 of the first chip 100.

Although not shown, an under fill film may be provided between the interposer substrate 1100 and the first chip structure 10. The under fill film may be in (e.g., may fill) a space between the interposer substrate 1100 and the first chip 100, and may surround the connection terminals 105.

The chip stack CS and the fourth semiconductor chip 700 may be disposed on the interposer substrate 1100. The chip stack CS and the fourth semiconductor chip 700 may be disposed horizontally spaced apart from the first chip structure 10. The chip stack CS and the fourth semiconductor chip 700 may also be horizontally spaced apart from each other.

The chip stack CS may include a base substrate, third semiconductor chips 620 stacked on the base substrate, and a second molding layer 630 surrounding the third semiconductor chips 620. Hereinafter, configurations of the chip stack CS will be described in detail.

The base substrate may be a base semiconductor chip 610. For example, the base substrate may be a wafer-level semiconductor substrate made of semiconductor such as silicon (Si). Hereinafter, the base semiconductor chip 610 refers to the same component as the base substrate, and may use the same reference numeral or symbol as the base substrate.

The base semiconductor chip 610 may include a base circuit layer 612 and base penetration electrodes 614. The base circuit layer 612 may be provided on a lower surface of the base semiconductor chip 610. The base circuit layer 612 may include an integrated circuit. For example, the base circuit layer 612 may be a memory circuit. That is, the base semiconductor chip 610 may be a memory chip such as dynamic random-access memory (DRAM), static random-access memory (SRAM), magnetoresistive random-access memory (MRAM), or flash memory. The base penetration electrodes 614 may penetrate the base semiconductor chip 610 in a direction vertical (e.g., perpendicular) to an upper surface of the interposer substrate 1100. The base circuit layer 612 and the base penetration electrodes 614 may be electrically connected to each other. A lower surface of the base semiconductor chip 610 may be an active surface. FIG. 9 illustrates that the base substrate includes the base semiconductor chip 610, but the inventive concepts are not limited thereto. According to other embodiments of the inventive concepts, the base substrate may not include the base semiconductor chip 610.

The base semiconductor chip 610 may further include a protective film, and base connection terminals 616. The protective film may be disposed on a lower surface of the base semiconductor chip 610 to cover the base circuit layer 612. The protective film may include silicon nitride (SiN). The base connection terminals 616 may be provided on the lower surface of the base semiconductor chip 610. The base connection terminals 616 may be electrically connected to a power circuit, a ground circuit, or an input-output circuit (that is, the memory circuit) of the base circuit layer 612. The base connection terminals 616 may be exposed from the protective film.

The third semiconductor chip 620 may be mounted on the base semiconductor chip 610. That is, the third semiconductor chips 620 may constitute a chip-on-wafer (COW) structure with the base semiconductor chip 610. The third semiconductor chip 620 may have a smaller width than the base semiconductor chip 610.

The third semiconductor chip 620 may include a third circuit layer 622 and chip penetration electrodes 624. The third circuit layer 622 may include a memory circuit. That is, the third semiconductor chips 620 may be a memory chip such as DRAM, SRAM, MRAM, or flash memory. The third circuit layer 622 may include the same circuit as the base circuit layer 612, but the inventive concepts are not limited thereto. The chip penetration electrodes 624 may penetrate the third semiconductor chips 620 in a direction vertical to an upper surface of the interposer substrate 1100. The chip penetration electrodes 624 and the third circuit layer 622 may be electrically connected to each other. A lower surface of the third semiconductor chip 620 may be an active surface. First chip bumps 626 may be provided on the lower surface of the third semiconductor chip 620. The first chip bumps 626 may electrically connect the base semiconductor chip 610 and the third semiconductor chip 620 between the base semiconductor chip 610 and the third semiconductor chip 620.

The third semiconductor chip 620 may be provided in plurality. For example, a plurality of third semiconductor chips 620 may be stacked (e.g., may be vertically stacked) on the base semiconductor chip 610. In some embodiments, four to thirty-two third semiconductor chips 620 may be stacked. The first chip bumps 626 may be respectively provided between the third semiconductor chips 620. In this case, the uppermost third semiconductor chip 620 may not include the chip penetration electrodes 624. In addition, the uppermost third semiconductor chip 620 may have a greater thickness than the third semiconductor chips 620 disposed thereunder.

Although not shown, an adhesive layer may be provided between the third semiconductor chips 620. The adhesive layer may include a non-conductive film (NCF). The adhesive layer may be interposed between the first chip bumps 626 between the third semiconductor chips 620 to prevent an electrical short circuit between the first chip bumps 626.

The second molding layer 630 may be disposed on an upper surface of the base semiconductor chip 610. The second molding layer 630 may be on (e.g., may cover) the base semiconductor chip 610, and may surround the third semiconductor chips 620. The upper surface of the second molding layer 630 may be coplanar with the upper surface of the uppermost third semiconductor chip 620, and the uppermost third semiconductor chip 620 may be exposed from the second molding layer 630. The second molding layer 630 may include an insulating polymer material. For example, the second molding layer 630 may include an epoxy molding compound (EMC).

The chip stack CS may be mounted on the interposer substrate 1100. For example, the chip stack CS may be connected to the first substrate line pattern 1124 of the interposer substrate 1100 through the base connection terminals 616 of the base semiconductor chip 610. The base connection terminals 616 may be provided between the base circuit layer 612 and the first substrate line pattern 1124 of the interposer substrate 1100.

Although not shown, an under fill film may be provided between the interposer substrate 1100 and the chip stack CS. The under fill film may be in (e.g., may fill) a space between the interposer substrate 1100 and the base semiconductor chip 610, and may surround the base connection terminals 616.

The fourth semiconductor chip 700 may be disposed on the interposer substrate 1100. The fourth semiconductor chip 700 may be disposed spaced apart from the chip stack CS. The fourth semiconductor chip 700 may have substantially the same thickness as the chip stack CS. The fourth semiconductor chip 700 may include a semiconductor material such as silicon (Si). The fourth semiconductor chip 700 may include a fourth circuit layer 710. The fourth circuit layer 710 may include a logic circuit. That is, the fourth semiconductor chip 700 may be a logic chip. For example, the fourth semiconductor chip 700 may be a system-on-chip (SOC). A lower surface of the fourth semiconductor chip 700 may be an active surface, and an upper surface of the fourth semiconductor chip 700 may be an inactive surface.

Second chip bumps 702 may be provided on the lower surface of the fourth semiconductor chip 700. The second chip bumps 702 may be electrically connected to a power circuit, a ground circuit, or an input-output circuit (that is, the logic circuit) of the fourth circuit layer 710.

The fourth semiconductor chip 700 may be mounted on the interposer substrate 1100. For example, the fourth semiconductor chip 700 may be connected to the first substrate line pattern 1124 of the interposer substrate 1100 through the second chip bumps 702. The second chip bumps 702 may be provided between the first substrate line pattern 1124 of the interposer substrate 1100 and the fourth circuit layer 710 of the fourth semiconductor chip 700.

Although not shown, an under fill film may be provided between the interposer substrate 1100 and the fourth semiconductor chip 700. The under fill film may be in (e.g., may fill) a space between the interposer substrate 1100 and the fourth semiconductor chip 700, and may surround the second chip bumps 702.

A third molding layer 800 may be provided on the interposer substrate 1100. The third molding layer 800 may be on (e.g., may cover) the upper surface of the interposer substrate 1100. The third molding layer 800 may surround the first chip structure 10, the chip stack CS and the fourth semiconductor chip 700. The third molding layer 800 may expose the upper surface of the first chip structure 10, the upper surface of the chip stack CS and the upper surface of the fourth semiconductor chip 700. For example, the third molding layer 800 may include an insulating material. For example, the third molding layer 800 may include an epoxy molding compound (EMC).

FIG. 9 illustrates that the first chip structure 10 is mounted on the interposer substrate 1100, but the inventive concepts are not limited thereto.

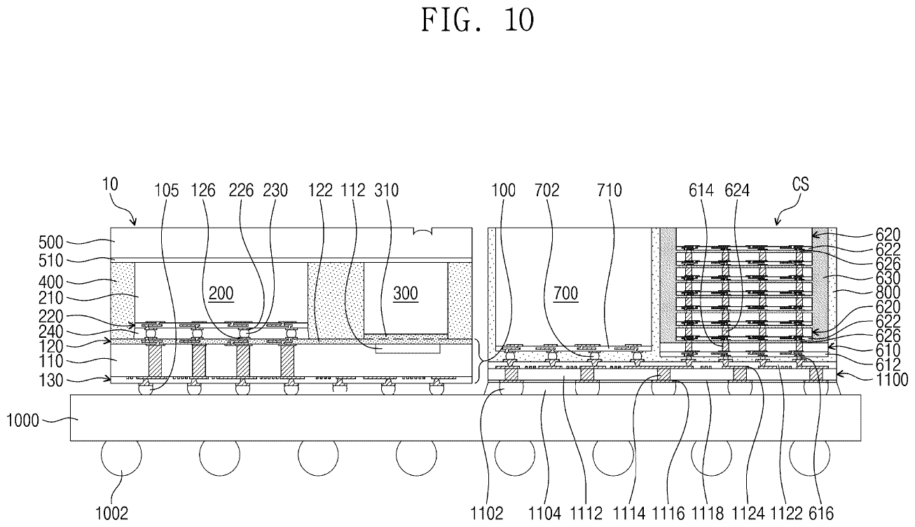

FIG. 10 is a cross-sectional view for describing a semiconductor package according to embodiments of the inventive concepts.

Referring to FIG. 10, the first chip structure 10 may be provided on the package substrate 1000. The first chip structure 10 may be disposed horizontally spaced apart from the interposer substrate 1100. The first chip structure 10 may be mounted on an upper surface of the package substrate 1000. For example, the first chip structure 10 may be connected to the pads of the package substrate 1000 through the connection terminals 105 of the first chip 100. The connection terminals 105 may be provided between the pads of the package substrate 1000 and the lining layer 130 of the first chip 100. The connection terminals 105 may electrically connect the first chip structure 10 to the package substrate 1000. For example, the first chip structure 10 may be mounted on the package substrate 1000 in a flip chip manner.

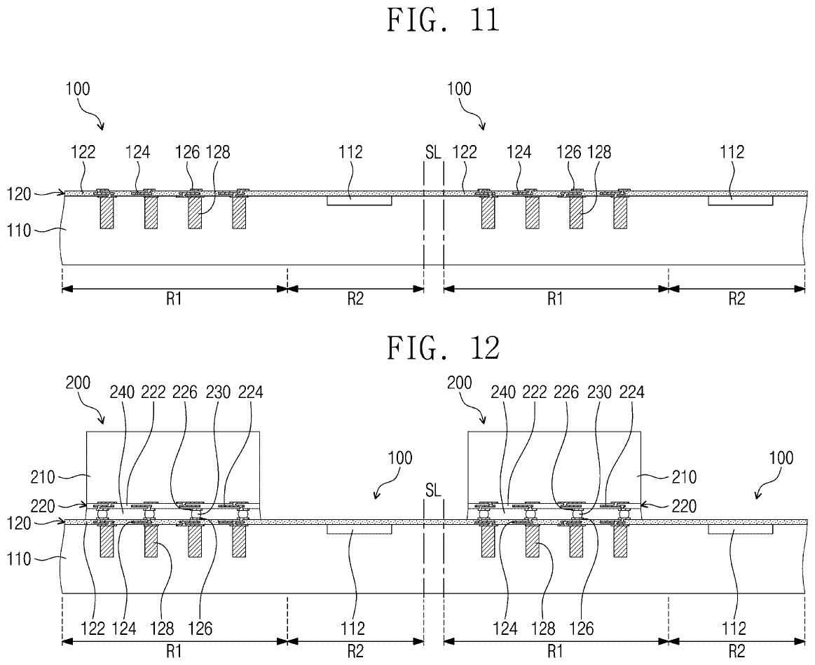

FIGS. 11 to 19 are cross-sectional views for describing a method for manufacturing a semiconductor package according to embodiments of the inventive concepts.

Referring to FIG. 11, the first chips 100 may be formed on one semiconductor wafer, for example, a first semiconductor substrate 110. For example, first integrated elements may be formed on an upper surface of the first semiconductor substrate 110. The first integrated elements may include a photonic integrated circuit (PIC). The sensor portions 112 may be formed on an upper portion of the first semiconductor substrate 110 on the second regions R2 of the first semiconductor substrate 110. The sensor portions 112 may be exposed onto the upper surface of the first semiconductor substrate 110. Holes may be formed on the upper surface of the first semiconductor substrate 110 on the first regions R1 of the first semiconductor substrate 110, and then the chip vias 128 may be formed by filling the insides of the holes with a conductive material. Upper ends of the chip vias 128 may be exposed onto the upper surface of the first semiconductor substrate 110. Lower ends of the chip vias 128 may be disposed inside the first semiconductor substrate 110. The first circuit layer 120 may be formed on the upper surface of the first semiconductor substrate 110. For example, the first insulating layer 122 may be formed by forming an insulating layer on (e.g., covering) the upper surface of the first semiconductor substrate 110, and patterning the insulating layer. In other words, the first insulating layer 122 may be formed by forming an insulating layer on an active surface of the first chip 100. The first element line portion 124 may be formed by forming a conductive layer on the first insulating layer 122 and patterning the conductive layer. The first insulating layer 122 and the first element line portion 124 may be formed by repeatedly performing deposition and patterning the insulating layer and deposition and patterning the conductive layer.

Referring to FIG. 12, the second chips 200 may be provided. The second chips 200 may be substantially the same as or similar to the second chip 200 described with reference to FIGS. 1 to 9.

The second chips 200 may be mounted on the first chips 100. The second chips 200 may be mounted on the first chips 100 in a flip chip manner. The first connection terminals 230 may be provided on the lower surfaces of the second chips 200. The first connection terminals 230 may include a solder ball or solder bump. The first under fill layers 240 surrounding the first connection terminals 230 may be provided on the lower surfaces of the second chips 200. For example, the first under fill layers 240 may be non-conductive adhesives or films. When the first under fill layers 240 are non-conductive adhesives, the first under fill layers 240 may be formed in a manner in which the liquid-phase non-conductive adhesives are applied on the lower surfaces of the second chips 200 through dispensing. When the first under fill layers 240 are the non-conductive films, the first under fill layers 240 may be formed in a manner in which the non-conductive films are attached to the lower surfaces of the second chips 200. Thereafter, the second chips 200 may be aligned such that the first connection terminals 230 are located on the first chip pads 126 of the first chips 100, and then a reflow process may be performed on the second chips 200.

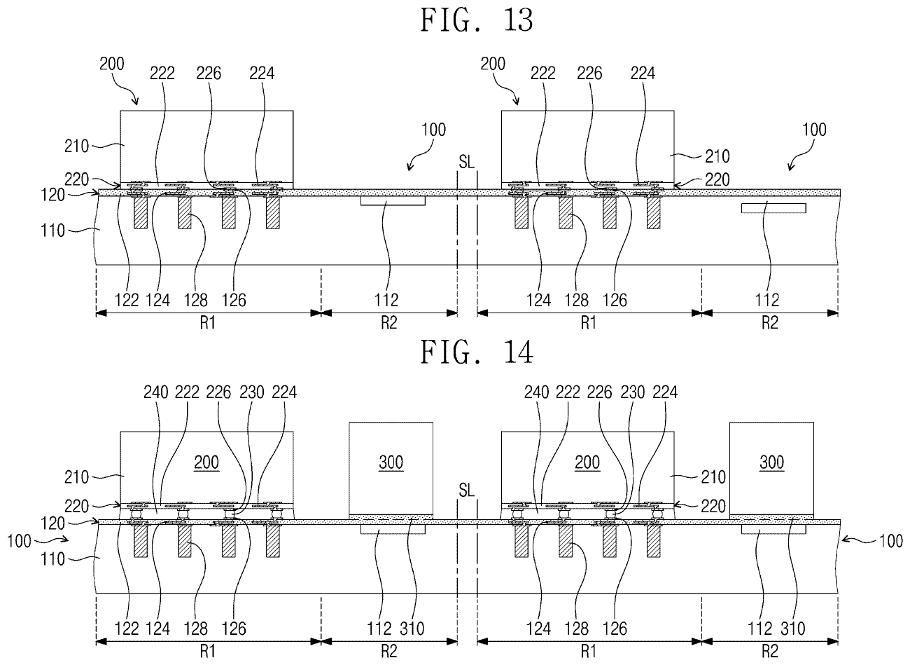

According to other embodiments, as illustrated in FIG. 13, the second chips 200 may be bonded onto the first chips 100. The second chips 200 may be moved such that the lower surfaces of the second chips 200 are in contact with the upper surfaces of the first chips 100. The second chip pads 226 of the second chips 200 may be aligned with the first chip pads 126 of the first chips 100. The second chip pads 226 and the first chip pads 126 may be in contact with each other. A heat treatment process may be performed on the first chips 100 and the second chips 200. The first chip pads 126 and the second chip pads 226 may be bonded to each other by the heat treatment process. For example, the first chip pads 126 may be bonded to and may be integrally formed with the second chip pads 226. The second chip pads 226 and the first chip pads 126 may be naturally bonded to each other. Specifically, the first chip pads 126 and the second chip pads 226 may be composed of the same material (for example, copper (Cu) or the like), and may be bonded to each other by an intermetallic hybrid bonding process by surface activation on a boundary surface of the first chip pads 126 and the second chip pads 226 in contact with each other. The first chip pads 126 and the second chip pads 226 may be bonded to each other by the heat treatment process. Hereinafter, description will be made with reference to embodiments where the first connection terminals 230 are provided on the lower surfaces of the second chips 200 (e.g., see FIG. 12), but the present disclosure is not limited thereto.

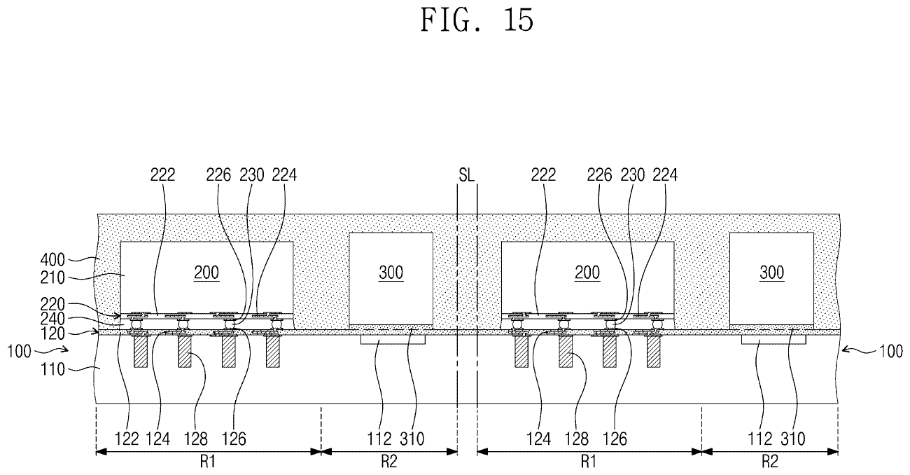

Referring to FIG. 14, the support blocks 300 may be formed. The support blocks 300 may be blocks composed of a single material. For example, the support blocks 300 may include bulk silicon (Si). The third insulating layer 310 may be formed on the lower surfaces of the support blocks 300. For example, the third insulating layer 310 may be formed by performing an oxidation process, a nitridation process, or an oxynitridation process on the lower surface of the support blocks 300. As another example, the third insulating layers 310 may be layers formed by natural oxidation of the lower surfaces of the support blocks 300.

The support blocks 300 may be disposed on the first chips 100. The support blocks 300 may be disposed on the second regions R2 of the first chips 100. The lower surfaces of the support blocks 300, that is, the lower surfaces of the third insulating layers 310 may be in contact with the first insulating layer 122. For example, the first chips 100 and the support blocks 300 may be brought into contact such that the first insulating layer 122 and the third insulating layers 310 are in contact with each other on the sensor portions 112. The third insulating layers 310 and the first insulating layer 122 may be bonded to each other. A heat treatment process may be performed on the third insulating layers 310 and the first insulating layer 122. The first insulating layer 122 and the third insulating layers 310 may be bonded to each other by the heat treatment process. For example, the first insulating layer 122 may be bonded to and may be integrally formed with the third insulating layer 310. The third insulating layers 310 and the first insulating layer 122 may be naturally bonded to each other. Specifically, the first insulating layer 122 and the third insulating layers 310 may be composed of the same material (for example, silicon oxide (SiO) or the like), and may be bonded to each other by material diffusion in an oxide/nitride/oxynitride on a boundary surface of the first insulating layer 122 and the third insulating layers 310 in contact with each other. The first insulating layer 122 and the third insulating layers 310 may be bonded to each other by the heat treatment process.

Referring to FIG. 15, the first molding layer 400 may be formed. For example, the first molding layer 400 may be formed by applying an insulating material on the first chips 100. The first molding layer 400 may be on (e.g., may cover) the second chips 200 and the support blocks 300.

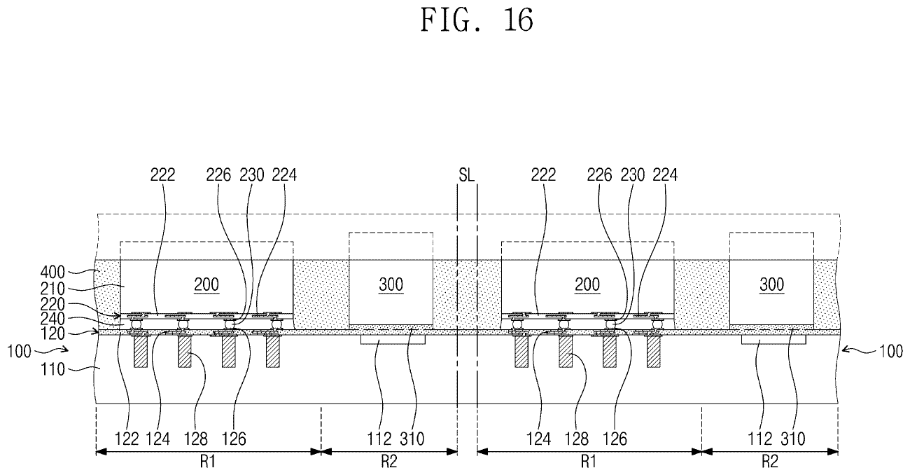

Referring to FIG. 16, a grinding process (i.e., a thinning process) may be performed on the first molding layer 400. An upper portion of the first molding layer 400 may be partially removed. The grinding process may be performed until the upper surfaces of the second chips 200 and the upper surfaces of the support blocks 300 are exposed. The upper surfaces of the first molding layers 400 may be coplanar with the upper surfaces of the second chips 200 and the upper surfaces of the support blocks 300.

According to other embodiments, when heights of the support blocks 300 are higher than heights of the second chips 200, the grinding process may be performed until the upper surfaces of the support blocks 300 are exposed. At this time, the second chips 200 may be buried by the first molding layer 400, and may not be exposed onto the upper surface of the first molding layer 400. In this case, the semiconductor package described with reference to FIG. 3 may be manufactured.

According to embodiments of the inventive concepts, the second chips 200 and the support blocks 300 may be formed to have small thicknesses as needed. More specifically, after the second chips 200 are mounted on and the support blocks 300 are bonded onto the first chips 100, a thinning process may be performed with the first molding layer 400, and the second chips 200 and the support blocks 300 may have smaller thicknesses. Accordingly, the semiconductor package with a small size may be provided.

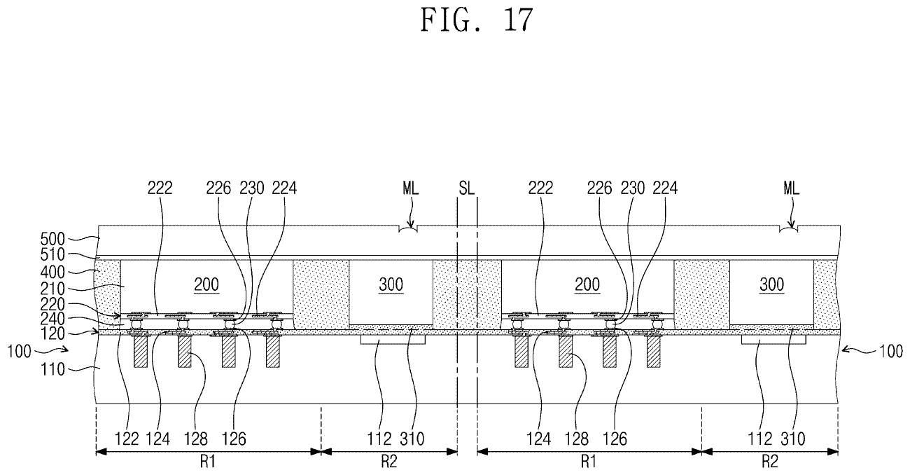

Referring to FIG. 17, the micro-lens layer 500 may be provided. The micro-lens layer 500 may be substantially the same as or similar to the micro-lens layer 500 described with reference to FIGS. 1 to 9.

The micro-lens layer 500 may be disposed on the first molding layer 400. The micro-lens layer 500 may be adhered onto the upper surface of the first molding layer 400. For example, the first adhesive layer 510 may be provided on a lower surface of the micro-lens layer 500. The first adhesive layer 510 may be applied or attached to the lower surface of the micro-lens layer 500 depending on a form of the first adhesive layer 510. The micro-lens layer 500 may be adhered to the upper surface of the first molding layer 400, the upper surface of the second chips 200 and the upper surface of the support blocks 300 by using the first adhesive layer 510.

According to embodiments of the inventive concepts, the first chips 100, the second chips 200, the support blocks 300, and the first molding layer 400 may be formed in a wafer-level, and the upper surfaces of the second chips 200, the upper surfaces of the support blocks 300 and the upper surface of the first molding layer 400 may be formed to be flatly coplanar with each other through a thinning process or grinding process. In addition, the micro-lens layer 500 may be also formed in a wafer-level, and may be adhered onto the second chips 200 and the support blocks 300 by using the first adhesive layer 510. Accordingly, there may be fewer defects such as a void in the first adhesive layer 510 in a process of adhering the micro-lens layer 500.

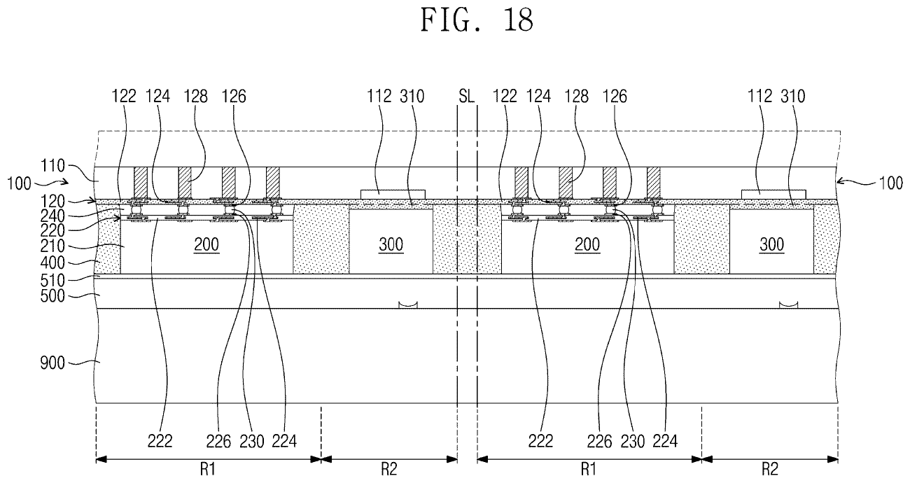

Referring to FIG. 18, a carrier substrate 900 may be attached onto the micro-lens layer 500. The carrier substrate 900 may be an insulating substrate including glass or polymer, or a conductive substrate including metal. Although not shown, an adhesive member may be provided on one surface of the carrier substrate 900 to attach the micro-lens layer 500 to the carrier substrate 900. For example, the adhesive member may include an adhesive tape.

Thereafter, a result of FIG. 17 may be turned over such that the first chip 100 is located on (e.g., above) the carrier substrate 900.

A grinding process may be performed on the first chip 100. For example, the grinding process may be performed on the upper surface of the first semiconductor substrate 110 of the first chip 100. An upper portion of the first semiconductor substrate 110 may be partially removed. The grinding process may be performed until the upper surfaces of the chip vias 128 are exposed. The upper surface of the first semiconductor substrate 110 may be coplanar with the upper surfaces of the chip vias 128.

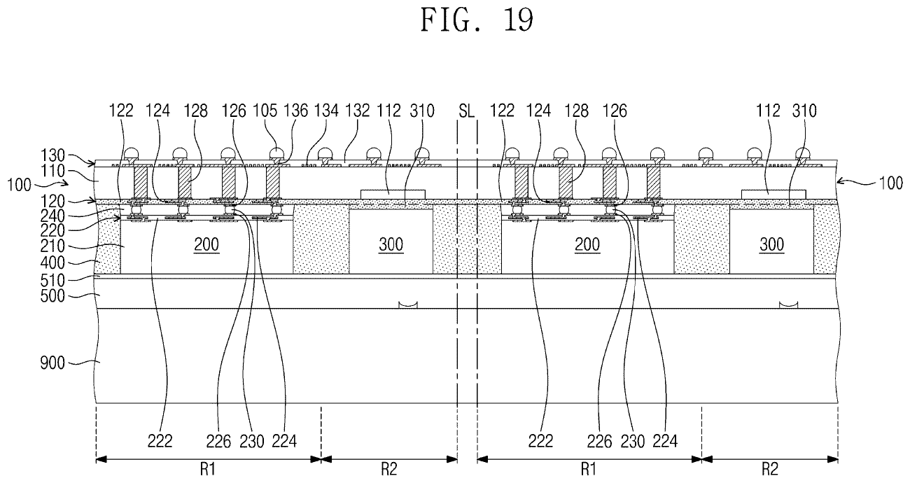

Referring to FIG. 19, the lining layer 130 may be formed on the first semiconductor substrate 110. For example, the fourth insulating layer 132 may be formed by forming an insulating layer on (e.g., covering) the upper surface of the first semiconductor substrate 110, and patterning the insulating layer. The third element line portion 134 may be formed by forming a conductive layer on the fourth insulating layer 132 and patterning the conductive layer. The fourth insulating layer 132 and the third element line portion 134 may be formed by repeatedly performing deposition and patterning the insulating layer and deposition and patterning the conductive layer. Thereafter, holes exposing the third element line portion 134 may be formed by patterning the fourth insulating layer 132, and the third chip pads 136 connected to the third element line portion 134 may be formed on the fourth insulating layer 132.

The connection terminals 105 may be provided on the third chip pads 136. The connection terminals 105 may be connected to the upper surfaces of the third chip pads 136.

Thereafter, the carrier substrate 900 may be removed.

A plurality of semiconductor packages may be separated into each other by performing a cutting process along a sawing line SL.

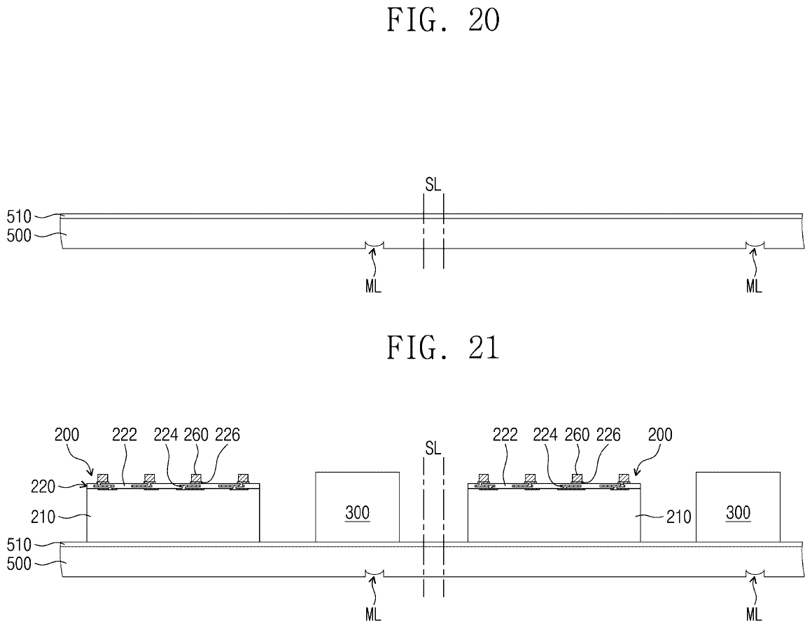

FIGS. 20 to 26 are cross-sectional views for describing a method for manufacturing a semiconductor package according to embodiments of the inventive concepts.

Referring to FIG. 20, the micro-lens layer 500 may be provided. The micro-lens layer 500 may be substantially the same as or similar to the micro-lens layer 500 described with reference to FIGS. 1 to 9. The micro-lenses ML may be provided on a lower surface of the micro-lens layer 500.

The first adhesive layer 510 may be provided on an upper surface of the micro-lens layer 500. The first adhesive layer 510 may be applied or attached to the upper surface of the micro-lens layer 500 depending on a form of the first adhesive layer 510.

Referring to FIG. 21, the second chips 200 and the support blocks 300 may be attached onto the micro-lens layer 500. The second chips 200 and the support blocks 300 may be attached (i.e., adhered) onto the upper surface of the micro-lens layer 500 by using the first adhesive layer 510.

The second chips 200 may be disposed in a face up form. For example, the second chip pads 226 of the second chips 200 may face upward.

The chip bumps 260 may be formed on the second chip pads 226 of the second chips 200. The chip bumps 260 may include a solder bump. According to other embodiments, instead of the chip bumps 260, conductive posts or connection terminals (e.g., see the first connection terminals 230 of FIG. 1) connecting the first chip pads 126 and the second chip pads 226 may be provided.

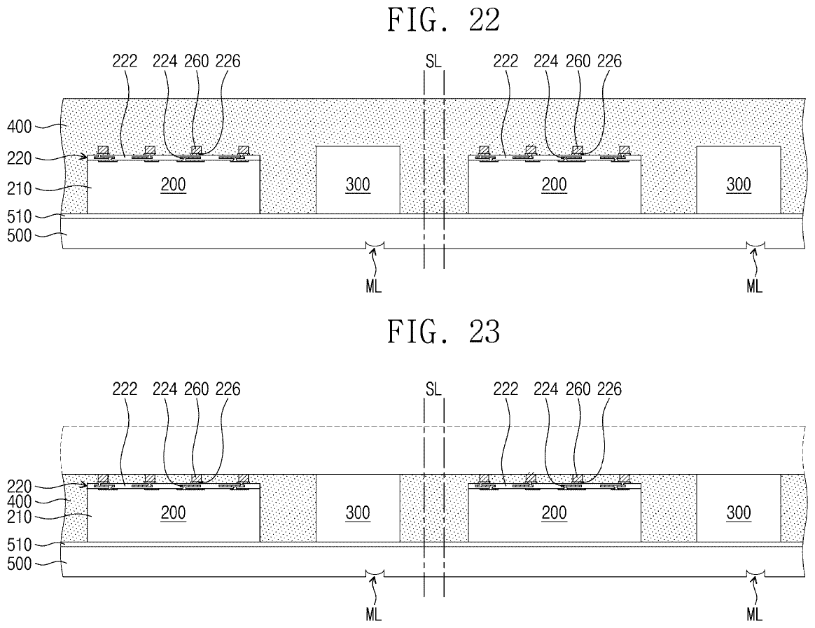

Referring to FIG. 22, the first molding layer 400 may be formed. For example, the first molding layer 400 may be formed by applying an insulating material on the micro-lens layer 500. The first molding layer 400 may be on (e.g., may cover) the second chips 200 and the support blocks 300.

Referring to FIG. 23, a grinding process may be performed on the first molding layer 400. An upper portion of the first molding layer 400 may be partially removed. The grinding process may be performed until the upper surfaces of the chip bumps 260 and the upper surfaces of the support blocks 300 are exposed. The upper surfaces of the first molding layers 400 may be coplanar with the upper surfaces of the chip bumps 260 and the upper surfaces of the support blocks 300.

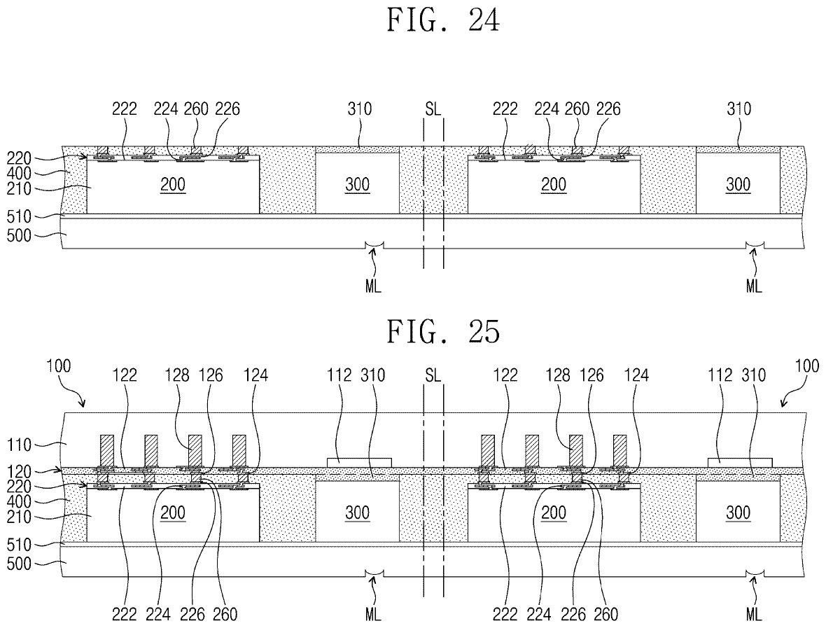

Referring to FIG. 24, the third insulating layers 310 may be formed on upper portions of the support blocks 300. For example, the third insulating layers 310 may be formed by performing an oxidation process, a nitridation process, or an oxynitridation process on the upper surfaces of the support blocks 300 exposed after the grinding process. As another example, the third insulating layers 310 may be layers formed by natural oxidation of the upper surfaces of the support blocks 300.

Referring to FIG. 25, the first chips 100 may be formed on one semiconductor wafer. A process of forming the first chips 100 may be substantially the same as described above with reference to FIG. 11.

The first chips 100 may be disposed on the first molding layer 400. The first chips 100 may be bonded to the second chips 200 and the support blocks 300. For example, the first chips 100 may be bonded on the first molding layer 400, the second chips 200, and the support blocks 300. In some embodiments, the sensor portions 112 of the first chips 100 are on the support blocks 300. Hereinafter, bonding of the first chips 100 will be described in more detail.

The first chips 100 may be bonded onto the second chips 200. A semiconductor wafer may be moved such that the lower surfaces of the first chips 100 are in contact with the upper surfaces of the second chips 200. The first chip pads 126 of the first chips 100 may be aligned with the second chip pads 226 of the second chips 200. In some embodiments, the chip bumps 260 may connect the second chip pads 226 of the second chips 200 to the first chip pads 126 of the first chips 100. For example, the first chip pads 126 of the first chips 100 may be connected to upper surfaces of the chip bumps 260. In other embodiments, the second chip pads 226 and the first chip pads 126 may be in contact with each other. Hereinafter, description will be made with reference to embodiments where the second chip pads 226 and the first chip pads 126 are in contact with each other, but the present disclosure is not limited thereto.

A heat treatment process may be performed on the first chips 100 and the second chips 200. The first chip pads 126 and the second chip pads 226 may be bonded to each other by the heat treatment process. For example, the first chip pads 126 may be bonded to and may be integrally formed with the second chip pads 226. The second chip pads 226 and the first chip pads 126 may be naturally bonded to each other. Specifically, the first chip pads 126 and the second chip pads 226 may be composed of the same material (for example, copper (Cu) or the like), and may be bonded to each other by an intermetallic hybrid bonding process by surface activation on a boundary surface of the first chip pads 126 and the second chip pads 226 in contact with each other. The first chip pads 126 and the second chip pads 226 may be bonded to each other by the heat treatment process.

The lower surfaces of the first chips 100, that is, the lower surface of the first insulating layer 122 may be in contact with the third insulating layers 310 of the support blocks 300. For example, the first chips 100 and the support blocks 300 may be brought into contact such that the third insulating layers 310 and the first insulating layer 122 are in contact with each other. The third insulating layers 310 and the first insulating layer 122 may be bonded to each other. A heat treatment process may be performed on the third insulating layers 310 and the first insulating layer 122. The first insulating layer 122 and the third insulating layers 310 may be bonded to each other by the heat treatment process. For example, the first insulating layer 122 may be bonded to and may be integrally formed with the third insulating layer 310. The third insulating layers 310 and the first insulating layer 122 may be naturally bonded to each other. Specifically, the first insulating layer 122 and the third insulating layers 310 may be composed of the same material (for example, silicon oxide (SiO) or the like), and may be bonded to each other by material diffusion in an oxide/nitride/oxynitride on a boundary surface of the first insulating layer 122 and the third insulating layers 310 in contact with each other. The first insulating layer 122 and the third insulating layers 310 may be bonded to each other by the heat treatment process.

A process of bonding the first chip pads 126 and the second chip pads 226 and a process of bonding the third insulating layers 310 and the first insulating layer 122 may be simultaneously performed.

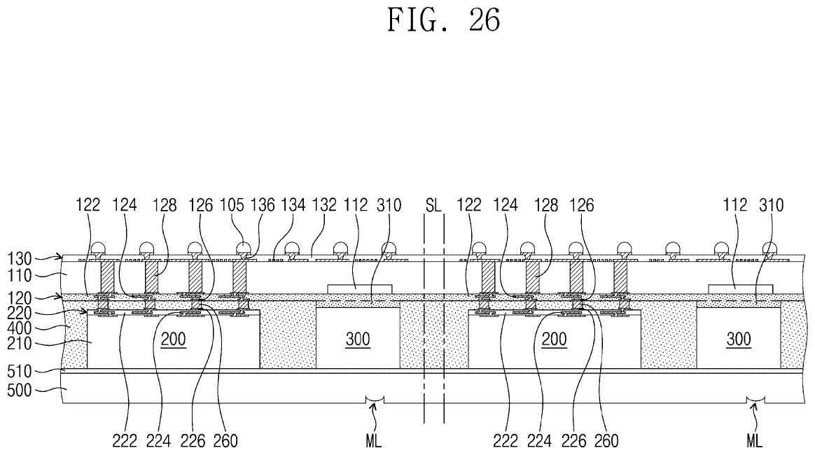

Referring to FIG. 26, a grinding process may be performed on the first chip 100. For example, the grinding process may be performed on the upper surface of the first semiconductor substrate 110 of the first chip 100. An upper portion of the first semiconductor substrate 110 may be partially removed. The grinding process may be performed until the upper surfaces of the chip vias 128 are exposed. The upper surface of the first semiconductor substrate 110 may be coplanar with the upper surfaces of the chip vias 128.

The lining layer 130 may be formed on the first semiconductor substrate 110. For example, the fourth insulating layer 132 may be formed by forming an insulating layer on (e.g., covering) the upper surface of the first semiconductor substrate 110 and patterning the insulating layer. The third element line portion 134 may be formed by forming a conductive layer on the fourth insulating layer 132 and patterning the conductive layer. The fourth insulating layer 132 and the third element line portion 134 may be formed by repeatedly performing deposition and patterning the insulating layer and deposition and patterning the conductive layer. Thereafter, holes exposing the third element line portion 134 may be formed by patterning the fourth insulating layer 132, and the third chip pads 136 connected to the third element line portion 134 may be formed on the fourth insulating layer 132.

The connection terminals 105 may be provided on the third chip pads 136. The connection terminals 105 may be connected to the upper surfaces of the third chip pads 136.

Thereafter, a plurality of semiconductor packages may be separated into each other by performing a cutting process along a sawing line SL.

In a semiconductor package according to embodiments of the inventive concepts, an insulating layer formed by oxidation or nitridation of a lower portion of a support block may be bonded to and may be integrally formed with an insulating layer of a first chip. Accordingly, the support block may be robustly attached or bonded to the first chip, and the semiconductor package with improved structural stability may be provided. In addition, a number of material layers transmitted by light may be small in a path of the light transmitting a translucent layer and entering a sensor portion of the first chip. Moreover, the support block may be provided with a material having high transmittance for the light to be received by the first chip so that light loss may be small. That is, the semiconductor package with improved optical characteristics may be provided.

Since a micro-lens layer is adhered by using a first adhesive layer, a process of manufacturing the semiconductor package may be simplified. In addition, there may be fewer defects such as a void in the first adhesive layer. Accordingly, there may be less loss of light that transmits through the first adhesive layer. That is, the semiconductor package with improved optical characteristics may be provided.

In a method for manufacturing a semiconductor package according to embodiments of the inventive concepts, after second chips are mounted on and support blocks are bonded onto first chips, a thinning process may be performed with a first molding layer, and the second chips and the support blocks may have smaller thicknesses. Accordingly, the semiconductor package with a small size may be provided.

As used herein, the terms “comprises”, “comprising”, “includes”, “including”, “has”, “having” and any other variations thereof specify the presence of the stated features, steps, operations, elements, components, and/or groups but do not preclude the presence or addition of one or more other features, steps, operations, elements, components, and/or groups thereof. In addition, it will be understood that, although the terms “first”, “second”, “third”, etc. may be used herein to describe various elements, these elements should not be limited by these terms. Rather, these terms are only used to distinguish one element from another. For example, a first element could be termed a second element, and, similarly, a second element could be termed a first element, without departing from the scope of the present disclosure.

Although example embodiments of the present disclosure have been described above, it will be understood that the present disclosure is not limited to the above-described embodiments and various changes and modifications can be made thereto by one of ordinary skill in the art without departing from the scope of the present disclosure as set forth in the appended claims.

What is claimed is:

1. A semiconductor package comprising:
a substrate;
a first chip on the substrate and comprising a photonic integrated circuit (PIC);
a second chip on the first chip and comprising an electronic integrated circuit (EIC);
a support block spaced apart from the second chip and bonded to an upper surface of the first chip;
a molding layer on the first chip and at least partially surrounding the second chip and the support block, wherein an upper surface of the support block is free of the molding layer;
a micro-lens layer on the molding layer, the first chip, and the support block; and
a first transparent adhesive layer between a lower surface of the micro-lens layer and an upper surface of the molding layer, and between the lower surface of the micro-lens layer and the upper surface of the support block.

2. The semiconductor package of claim 1, wherein the first transparent adhesive layer comprises an optical glue.

3. The semiconductor package of claim 1, wherein an upper surface of the second chip is free of the molding layer, and
wherein the first transparent adhesive layer is between the upper surface of the second chip and the lower surface of the micro-lens layer.

4. The semiconductor package of claim 1, wherein the molding layer is on an upper surface of the second chip, and
wherein at least a portion of the molding layer is between the upper surface of the second chip and the first transparent adhesive layer.

5. The semiconductor package of claim 1, wherein a lower surface of the support block is in contact with the upper surface of the first chip.

6. The semiconductor package of claim 5, wherein the first chip comprises a first insulating layer at the upper surface of the first chip,
wherein the support block comprises a second insulating layer at the lower surface of the support block, and
wherein the first insulating layer and the second insulating layer are in contact with each other and include a same material.

7. The semiconductor package of claim 6, wherein the first insulating layer and the second insulating layer comprise an oxide, a nitride, or an oxynitride of a material included in the support block.

8. The semiconductor package of claim 1, further comprising a second transparent adhesive layer between the upper surface of the first chip and a lower surface of the support block.

9. The semiconductor package of claim 1, wherein the support block is configured to pass light having a wavelength in a range of about 700 nm to about 1500 nm.

10. The semiconductor package of claim 9, wherein the support block comprises silicon (Si).

11. The semiconductor package of claim 1, wherein the support block has a thickness in a range of about 1 μm to about 500 μm.

12. The semiconductor package of claim 1, wherein the first chip further comprises a sensor portion,
wherein the support block is on the sensor portion, and
wherein the sensor portion is configured to receive light that enters the micro-lens layer and passes through the support block.

13. The semiconductor package of claim 1, wherein the second chip is mounted on the first chip in a flip chip manner, or
wherein a first chip pad of the first chip is in contact with a second chip pad of the second chip.

14. The semiconductor package of claim 1, further comprising:
a chip stack on the substrate and spaced apart from the first chip; and
a third chip on the substrate and spaced apart from the first chip and the chip stack,
wherein the chip stack comprises fourth chips that are stacked on the substrate.

15. A semiconductor package comprising:
a first chip comprising a photonic integrated circuit (PIC) and a sensor portion on an upper surface of the first chip;
a second chip on the upper surface of the first chip and comprising an electronic integrated circuit (EIC);
a support block on the upper surface of the first chip, spaced apart from the second chip, and on the sensor portion;
a molding layer on the first chip and at least partially surrounding the second chip and the support block; and
a micro-lens layer on the molding layer and adhered to the support block, wherein a micro-lens of the micro-lens layer is above the support block,
wherein the first chip comprises a first insulating layer at the upper surface of the first chip,
wherein the support block comprises a second insulating layer at a lower surface of the support block, and
wherein the first insulating layer and the second insulating layer are in contact with each other and include a same material.

16. The semiconductor package of claim 15, further comprising a first transparent adhesive layer between a lower surface of the micro-lens layer and an upper surface of the molding layer, and between the lower surface of the micro-lens layer and an upper surface of the support block.

17. The semiconductor package of claim 16, wherein the first transparent adhesive layer comprises an optical glue.

18. The semiconductor package of claim 16, wherein an upper surface of the second chip is free of the molding layer, and
wherein the first transparent adhesive layer is between the upper surface of the second chip and the lower surface of the micro-lens layer.

19. The semiconductor package of claim 16, wherein the molding layer is on an upper surface of the second chip, and
wherein at least a portion of the molding layer is between the upper surface of the second chip and the first transparent adhesive layer.

20. The semiconductor package of claim 15, wherein the sensor portion is configured to receive light that enters the micro-lens layer and passes through the support block, and
wherein the support block is configured to pass light having a wavelength in a range of about 700 nm to about 1500 nm.
